(19) United States
(12) Patent Application Publication
(10) Pub. No.: US 2016/0071853 A1
(43) Pub. Date: Mar. 10, 2016

(54) SEMICONDUCTOR MEMORY DEVICE

(71) Applicant: KABUSHIKI KAISHA TOSHIBA, Tokyo (JP)

(72) Inventor: Ryuji OHBA, Yokkaichi Mie (JP)

(21) Appl. No.: 14/634,709

(22) Filed: Feb. 27, 2015

Related U.S. Application Data
(60) Provisional application No. 62/048,174, filed on Sep. 9, 2014.

(51) Int. Cl. H01L 27/115; H01L 29/423; H01L 29/49; H01L 29/06; H01L 29/51

(52) U.S. Cl. CPC H01L 27/11521; H01L 29/0642; H01L 29/517; H01L 29/495; H01L 29/4966; H01L 29/4975; H01L 29/42324; H01L 29/42364

(57) ABSTRACT

A semiconductor memory device includes a semiconductor substrate, a plurality of element regions that extend in a first direction on an upper surface of the semiconductor substrate, and are arranged in parallel along a second direction crossing the first direction, an element isolation region that is disposed between the element regions, and a charge storage layer and a control gate that are disposed in each of the element regions, each of the charge storage layers having a portion whose width decreases with increasing distance away from the element region. A first insulating film is independently disposed on each of the charge storage layers, and second and third insulating films are disposed over each of the first insulating films.

### CROSS-REFERENCE TO RELATED APPLICATION

This application is based upon and claims the benefit of priority from U.S. Patent Application No. 62/048,174, filed Sep. 9, 2014, the entire contents of which are incorporated herein by reference.

### FIELD

Embodiments described herein relate generally to a semiconductor memory device.

### BACKGROUND

In a semiconductor memory device, for example, in a NAND-type flash memory device, it is difficult to suppress interference between adjacent cells while increasing capacitance between a floating gate electrode and a control gate electrode.

### DESCRIPTION OF THE DRAWINGS

FIG. 1 is a diagram schematically illustrating a planar layout pattern of a part of a cell array of a NAND-type flash memory device according to a first embodiment.

FIG. 2 is a vertical sectional view taken along line 2-2 of FIG. 1.

FIGS. 3 to 8 are diagrams illustrating a manufacturing method of the NAND-type flash memory device according to the first embodiment.

FIG. 9 is a diagram illustrating a portion of region G portion in FIG. 2 in an enlarged manner.

FIG. 10 is a vertical sectional view illustrating a NAND-type flash memory device according to a second embodiment.

FIGS. 11 to 13 diagrams illustrating a manufacturing method of the NAND-type flash memory device according to the second embodiment.

FIG. 14 is a vertical sectional view illustrating a NAND-type flash memory device according to a third embodiment.

FIGS. 15 to 19 are diagrams illustrating a manufacturing method of the NAND-type flash memory device according to the third embodiment.

FIG. 20 is a vertical sectional view illustrating a NAND-type flash memory device according to a fourth embodiment.

FIGS. 21 to 24 are diagrams illustrating a manufacturing method of the NAND-type flash memory device according to the fourth embodiment.

FIGS. 25 to 32 are vertical sectional views of modification examples.

### DETAILED DESCRIPTION

In general, according to one embodiment, a semiconductor memory device includes: a semiconductor substrate, a plurality of element regions that extend in a first direction on an upper surface of the semiconductor substrate, and are arranged in parallel along a second direction crossing the first direction, an element isolation region that is disposed between the element regions, and a charge storage layer and a control gate that are disposed in each of the element regions, each of the charge storage layers having a portion whose width decreases with increasing distance away from the element region. A first insulating film is independently disposed on each of the charge storage layers, and second and third insulating films are disposed over each of the first insulating films.

### First Embodiment

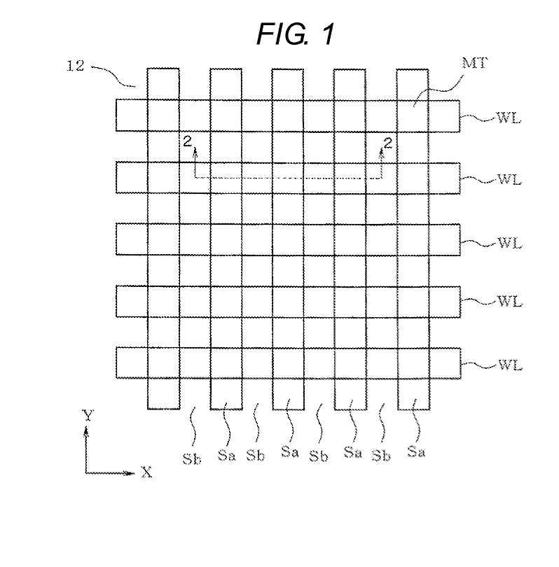

Hereinafter, an example in which a NAND-type flash memory device is applied as a semiconductor memory device will be described with reference to FIGS. 1 to 9. In the following description, the same reference numerals are applied to elements provided with the same functions and the same configurations. The drawings are schematic, and a relationship between a thickness and a planar dimension, a thickness ratio of each layer, and the like may not necessarily be the same as actual values. In addition, an upper direction, a lower direction, a right direction, and a left direction illustrate a relative direction when a circuit forming surface side is set on the upper side of a semiconductor substrate described later, and are not necessarily identical to that of a case where the directions are based on a gravity acceleration direction.

In addition, in the following description, for convenience of the description, an XYZ orthogonal coordinate system is used. In the coordinate system, two directions which are orthogonal to each other and parallel with an upper surface of the semiconductor substrate are the X direction and the Y direction, a word line WL extends in the X direction, and a bit line BL extends in the Y direction. A direction orthogonal to both of the X direction and the Y direction is the Z direction. Furthermore, in the description of the embodiments, a NAND-type flash memory device will be described as an example of the semiconductor memory device, and replaceable technologies may be employed as the semiconductor memory device. In the description and the drawings, the same reference numerals are applied to the same elements that have been already described with respect to the drawings, and the specific description thereof will be suitably omitted.

FIG. 1 is a diagram schematically illustrating a planar layout pattern of a part of a cell array of a NAND-type flash memory device according to a first embodiment.

In FIG. 1, on a semiconductor substrate 12, a plurality of element regions Sa extend in the Y direction, and are separately disposed in parallel at predetermined intervals in the X direction. In the semiconductor substrate 12, an element isolation region Sb having a shallow trench isolation (STI) structure in which an insulating film is embedded in an element isolation groove described later extends in the Y direction of the drawing. A plurality of element isolation regions Sb are formed at predetermined intervals in the X direction of the drawing.

Accordingly, an element region Sa extends along the Y direction, and a plurality of element regions Sa are separately formed in a surface layer portion of the semiconductor substrate 12 at predetermined intervals in the X direction. That is, the element isolation region Sb is disposed between the element regions Sa, and the semiconductor substrate 12 is divided into a plurality of element regions Sa by the element isolation region Sb.

A word line WL extends along a direction orthogonal to the element region Sa (the X direction in FIG. 1). A plurality of word lines WL are separately formed at predetermined intervals in the Y direction of the drawing. In an intersection portion between the word line WL and the element region Sa, a memory cell transistor MT is formed. The memory cell transistor MT is a memory cell. The word line WL is a gate MG of the memory cell transistor MT. Furthermore, the planar layout pattern illustrated in FIG. 1 is also applied to NAND-type flash memory devices according to a second embodiment and the subsequent embodiments described later.

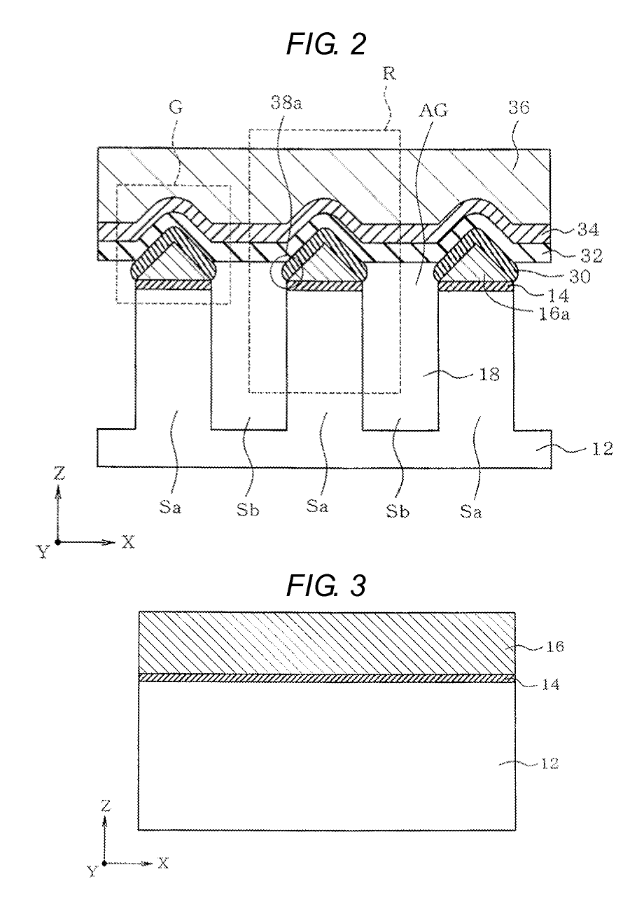

FIG. 2 is a vertical sectional view taken along line 2-2 of FIG. 1. A direction in which line 2-2 of FIG. 1 extends (the X direction in the drawing) is the direction in which the word line WL of FIG. 1 extends, and is a direction substantially perpendicular to the direction in which the element region Sa extends. In FIG. 2, a plurality of element isolation grooves 18 with a predetermined width are disposed in the upper surface of the semiconductor substrate 12. As the semiconductor substrate 12, for example, a silicon substrate may be used. In the element isolation groove 18, an air gap AG is formed, and thus the element isolation groove 18 becomes the element isolation region Sb. The air gap AG is hollowed. In addition, a thin silicon oxide film may be formed on an upper surface of the silicon substrate in the air gap AG.

The element region Sa is divided into a plurality of regions by the element isolation region Sb in a horizontal direction of the drawings. On the upper surface of the semiconductor substrate 12 in the element region Sa, a gate insulating film 14 is formed, and a floating gate (a charge storage film) electrode 16a is formed on the gate insulating film 14. The gate insulating film 14, for example, is formed of a silicon oxide film.

The floating gate electrode 16a, for example, is formed of a polysilicon. The floating gate electrode 16a has a triangular shape (more specifically, a substantially isosceles triangle) which protrudes upward in a cross sectional view. In other words, the floating gate electrode 16a has a shape which protrudes upward, orthogonal to the semiconductor substrate 12, when viewed from the semiconductor substrate 12 in the cross sectional view. In other words, the floating gate electrode 16a is formed such that a width in the X direction is gradually narrowed from the semiconductor substrate 12 side. A first insulating film 30, a second insulating film 32, and a third insulating film 34 are disposed on the floating gate electrode 16a. The first insulating film 30 and the third insulating film 34, for example, are formed of hafnium oxide (HfOₓ). Here, X is an arbitrary number.

The second insulating film 32, for example, is formed of a silicon oxide film. The first insulating film 30 is formed on the floating gate electrode 16a, and is disposed on the floating gate electrode 16a such that an end portion 38a of the first insulating film 30 slightly protrudes from a side end of the floating gate electrode 16a. As a result, the width of the first insulating film 30 in the X direction is greater than the width of the floating gate electrode 16a in the X direction. In addition, the first insulating film 30 is independently disposed on each floating gate electrode 16a.

The first insulating film 30 is separated from the first insulating films 30 on the adjacent floating gate electrodes 16a, and thus the first insulating films 30 are not in contact with each other. The second insulating film 32 and the third insulating film 34 are successively disposed to cross over a plurality of floating gate electrodes 16a (over the first insulating films 30) and the air gaps AG. On the third insulating film 34, a control gate electrode 36 is formed. The control gate electrode 36 covers a plurality of first insulating films 30 over the second insulating film 32 and the third insulating film 34, and is formed to be vertically cut along the horizontal direction of the drawing.

Furthermore, permittivities of the first insulating film 30, the second insulating film 32, and the third insulating film 34 satisfy the following relationships.

Permittivity of the first insulating film 30>permittivity of the second insulating film 32; and

Permittivity of the third insulating film 34>permittivity of the second insulating film 32.

According to the configuration described above, the width of the first insulating film 30 in the X direction is greater than the width of the floating gate electrode 16a in the X direction, and the first insulating film 30 is formed to protrude in the horizontal direction from a side end of the respective floating gate electrode 16a. In addition, the permittivity of the first insulating film 30 is higher than the permittivity of the second insulating film 32. Accordingly, the strength of the electric field from the floating gate electrode 16a toward the control gate electrode 36 increases by an amount of protrusion of the first insulating film 30 (a high permittivity portion) in the horizontal direction. Accordingly, the strength of the electric field which contributes to the forming of a capacitor between the floating gate electrode 16a and the control gate electrode 36 increases, and thus the capacitance between the control gate electrode 36 and the floating gate electrode 16a increases. Accordingly, writing characteristics and erasing characteristics of the NAND-type flash memory device according to this embodiment are improved.

In addition, the first insulating film 30 having high permittivity is separated between the memory cells. Accordingly, it is possible to suppress interference between the cells, and it is possible to improve reliability in the NAND-type flash memory device according to this embodiment.

FIG. 9 is a diagram illustrating a portion of region G in FIG. 2 in an enlarged manner. Here, a tangential angle θ of an upper inclined surface of the floating gate electrode 16a illustrated in FIG. 9 (a tilt angle of the upper inclined surface of the floating gate electrode 16a) will be described. It is preferable that the angle θ be 45 degrees. A large facing area between the control gate electrode 36 and the floating gate electrode 16a may be secured as the angle θ becomes larger, and thus it is possible to increase the capacitance between the control gate electrode 36 and the floating gate electrode 16a.

In addition, the electric field lines from the floating gate electrode 16a emanate in a perpendicular direction from the upper surface of the floating gate electrode 16a, and are directed toward the control gate electrode 36. Accordingly, the number of electric field lines which contributes to forming the capacitor between the control gate electrode 36 and the floating gate electrode 16a increases, and thus the capacitance between the control gate electrode 36 and the floating gate electrode 16a increases. On the other hand, the electric field lines (output perpendicularly from the upper surface of the floating gate electrode 16a) is more likely to be directed to the adjacent floating gate electrodes 16a as the angle θ becomes larger, such that the interference between the cells would increase, which is not preferable. Therefore, it is preferably that the angle θ be 45 degrees as a suitable angle at which most of the electric field lines from the floating gate electrode 16a are directed toward the control gate electrode 36 while securing an increase in the capacitance between the control gate electrode 36 and the floating gate electrode 16a. In addition, the angle θ that is able to secure the increase in the capacitance between the control gate electrode 36 and the floating gate electrode 16a and a trend in which the electric field lines from the floating gate electrode 16a are directed toward the control gate electrode 36, is in a range of 22.5 degrees<θ<67.5 degrees.

### Manufacturing Method of First Embodiment

Next, a manufacturing method of the semiconductor memory device according to the first embodiment will be described with reference to FIGS. 2 to 8. FIGS. 2 to 8 are diagrams illustrating the manufacturing method of the NAND-type flash memory device according to the first embodiment, illustrate vertical sectional views taken along line 2-2 of FIG. 1 during different steps in the manufacturing process, and are diagrams schematically illustrating a cross sectional structure in a direction along an extending direction of the word line WL (the X direction in FIG. 1).

First, to obtain the structure illustrated in FIG. 3, the gate insulating film 14, and the polysilicon film 16 are sequentially formed on the semiconductor substrate 12. As the semiconductor substrate 12, for example, a silicon substrate having p-type conductivity may be used. As the gate insulating film 14, for example, a silicon oxide film (SiO₂) may be used. The silicon oxide film, for example, may be formed by performing thermal oxidation with respect to the semiconductor substrate 12 (silicon) using a thermal oxidation method.

The polysilicon film 16, for example, may be formed by forming a non-doped polysilicon using a CVD method, and by introducing impurities into the polysilicon using an ion implantation method. As the impurities, for example, boron may be introduced. A mask film may be further disposed on the polysilicon film 16.

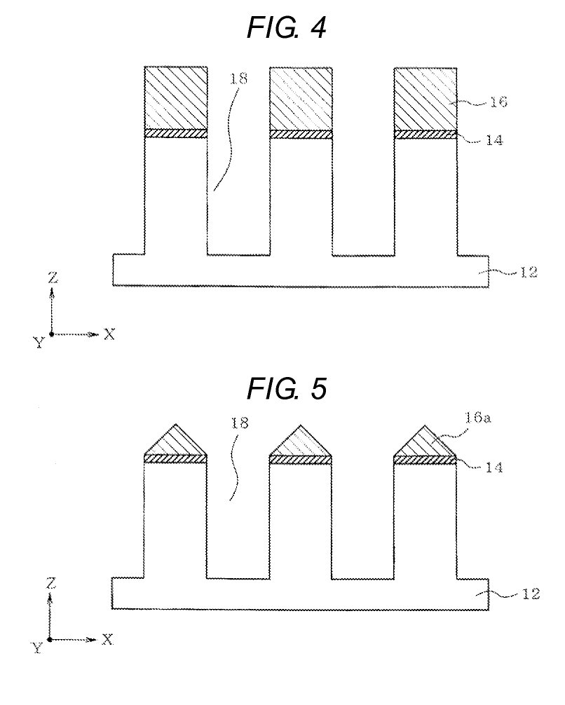

Next, to obtain the structure illustrated in FIG. 4, anisotropic dry etching is performed by using a lithography method and a Reactive Ion Etching (RIE) method, and thus the element isolation groove 18 is formed. During the etching, the polysilicon film 16, and the gate insulating film 14 are sequentially processed, and the semiconductor substrate 12 is further etched, and thus the element isolation groove 18 which is deeper than a lower surface of the gate insulating film 14 is formed.

Next, to obtain the structure illustrated in FIG. 5, a slimming treatment is performed with respect to the polysilicon film 16, and is processed such that the cross section has a triangular shape which protrudes upward (more specifically, a substantially isosceles triangle), and thus the floating gate electrode 16a is formed. The slimming may be performed in the same etching device following the etching by the RIE method described above. The slimming may be performed while allowing a resist formed by a lithography method to be retreated, or may be formed after removing the resist.

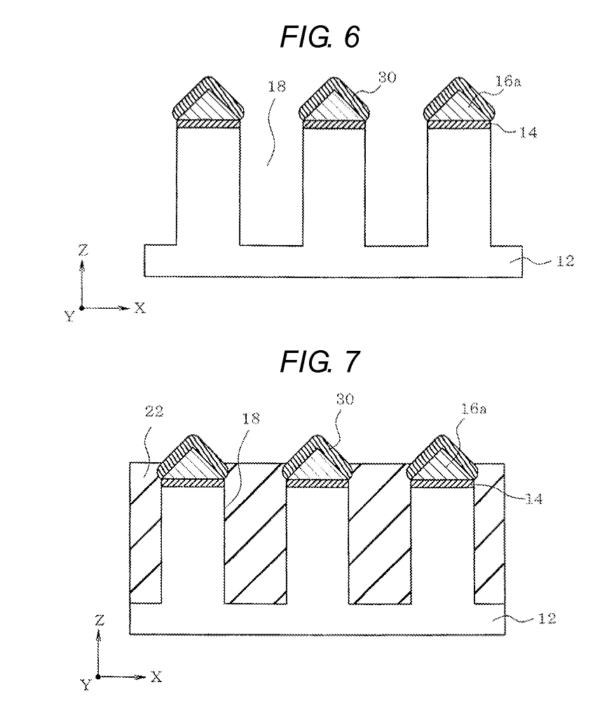

Next, to obtain the structure illustrated in FIG. 6, the first insulating film 30 is formed on the floating gate electrode 16a. As the first insulating film 30, for example, a hafnium oxide film (HfOₓ) may be used. Here, Xis an arbitrary number. Hafnium oxide is a non-stoichiometric compound, and may be formed as a compound of an arbitrary composition ratio. The hafnium oxide, for example, may be formed by using a Chemical Vapor Deposition (CVD) method. As the first insulating film 30, hafnium silicate (HfSiO) in which a small amount of Si is contained in hafnium oxide may be used.

The first insulating film 30 may be formed under a condition producing poor coverage. The first insulating film 30 is formed under the condition producing the poor coverage, and thus the first insulating film 30 is formed to cover only an upper portion of the floating gate electrode 16a, and is independently formed on each of the floating gate electrodes 16a. The first insulating film 30 on the floating gate electrode 16a is separated from the first insulating films 30 on the adjacent floating gate electrodes 16a, and thus the first insulating films 30 are not in contact with each other.

The first insulating film 30 is not formed in the element isolation groove 18. The first insulating film 30 is formed on a top surface of the floating gate electrode 16a such that an end portion 38a of the first insulating film 30 slightly protrudes from a side end of the floating gate electrode 16a. The width of the first insulating film 30 in the X direction is greater than the width of the floating gate electrode 16a in the X direction.

The first insulating film 30 may be formed to be thin in the element isolation groove 18 during forming the first insulating film 30. In this case, the thin first insulating film 30 which is stacked on an upper surface in the element isolation groove 18 may be removed by a wet etching such that the first insulating film 30 on the thickly stacked floating gate electrode 16a remains. When hafnium oxide, hafnium silicate, and the like are used as the first insulating film 30, sulfuric acid may be used as a chemical solution used for the wet etching.

Next, to obtain the structure illustrated in FIG. 7, an element isolation insulating film 22 is embedded in the element isolation groove 18. The element isolation insulating film 22 is embedded in the element isolation groove 18, and further, is formed to be sufficiently thick in order to cover a top surface of the first insulating film 30. As the element isolation insulating film 22, for example, a silicon oxide film is used. The element isolation insulating film 22, for example, may be formed by forming a silicon oxide film serving as a liner film using a CVD method, then by coating the silicon oxide film with a polysilazane solution using a spin coat method, and by performing a heat treatment with respect to the silicon oxide film in a water-vapor atmosphere. The polysilazane is a polymer having a basic structure of —SiH2-NH—, and is converted into a silicon oxide film by being annealed in a water-vapor atmosphere.

Subsequently, the element isolation insulating film 22 is subjected to etching back, and is retreated such that the top surface of the first insulating film 30 is exposed. The etching back, for example, may be performed by etching using a diluted hydrofluoric acid solution. An etching back amount of the element isolation insulating film 22 is controlled by adjusting an etching treatment time using the diluted hydrofluoric acid solution.

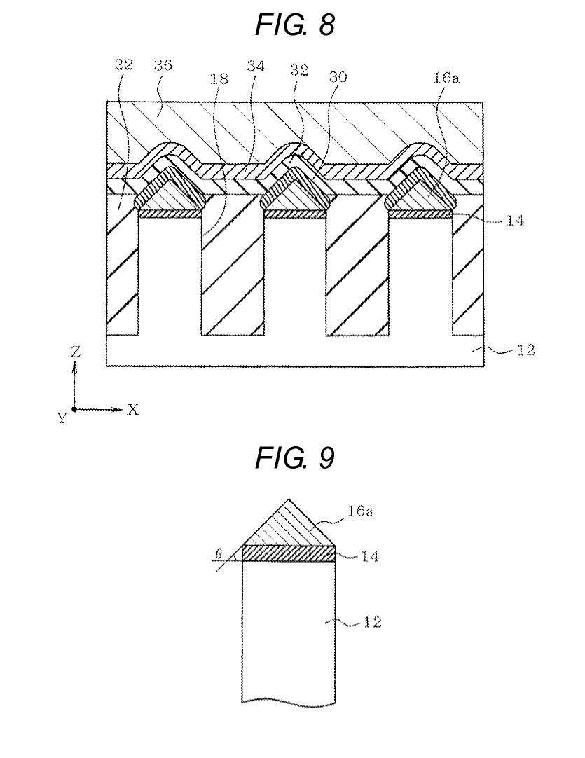

Next, to obtain the structure illustrated in FIG. 8, the second insulating film 32, the third insulating film 34, and the control gate electrode 36 are sequentially formed in order to cover the top surface of the first insulating film 30 and a top surface of the element isolation insulating film 22. As the second insulating film 32, for example, a silicon oxide film may be used. The silicon oxide film, for example, may be formed by using a CVD method. In addition, as the second insulating film 32, aluminum oxide may be used instead of the silicon oxide film.

As the third insulating film 34, for example, a hafnium oxide film may be used. The hafnium oxide film, for example, may be formed by using a CVD method. In addition, as the third insulating film 34, hafnium silicate (HfSiO) in which a small amount of Si is contained in hafnium oxide may be used. In addition, a laminated structure including tantalum oxide on hafnium oxide or hafnium silicate may be used.

As the control gate electrode 36, a metallic film may be used, and for example, tungsten (W) may be used. The tungsten, for example, may be formed by using a CVD method. In addition, as the control gate electrode 36, a conductive film may be used, and for example, tungsten nitride (WN) or tantalum nitride (TaN), or a laminated film thereof may be used.

Next, the floating gate electrode 16a, the first insulating film 30, the second insulating film 32, the third insulating film 34, and the control gate electrode 36 are etched to have the shape of the word line WL illustrated in FIG. 1. The etching, for example, may be performed by using a lithography method or an RIE method. The etching is stopped at the top surface of the element isolation insulating film 22. In a region between the word lines WL, the upper surface of the element isolation insulating film 22 is exposed.

Next, to obtain the structure illustrated in FIG. 2, the element isolation insulating film 22 is removed. The element isolation insulating film 22 may be removed, for example, by using a diluted hydrofluoric acid solution. The etching using the diluted hydrofluoric acid solution is performed from the upper surface of the element isolation insulating film 22 which is exposed in the region between the word lines WL. The element isolation insulating film 22 is a coarse film, and has a high etching rate compared to other films, and thus the element isolation insulating film 22 may be selectively etched and removed. According to such a process, a region in which the element isolation insulating film 22 is disposed is hollowed, and the hollowed region becomes the air gap AG.

After that, an interlayer insulating film, a contact, wiring, and the like are formed (not illustrated) by using a known technology, and thus the NAND-type flash memory device according to this embodiment may be formed.

### Second Embodiment

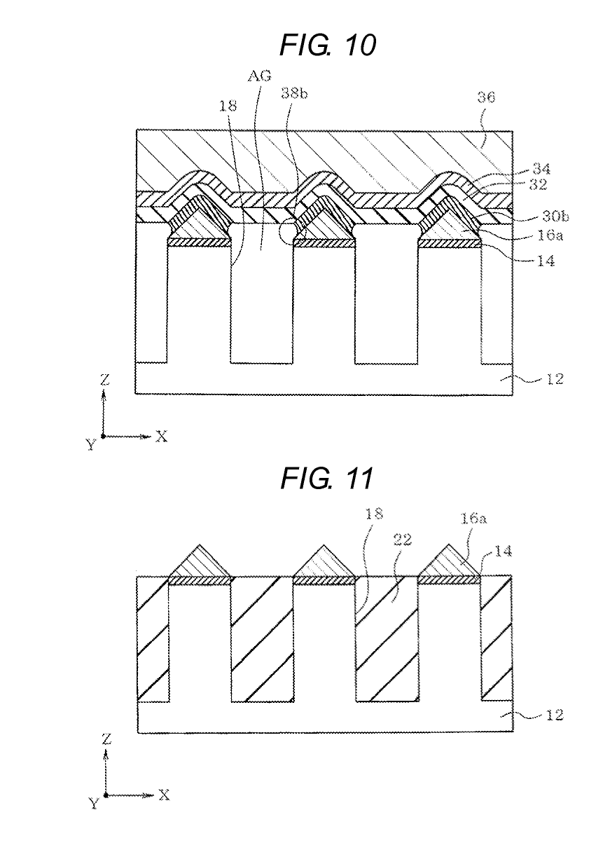

Hereinafter, a second embodiment will be described with reference to FIG. 10. FIG. 10 is a vertical sectional view illustrating a NAND-type flash memory device according to the second embodiment, and illustrates a cross section taken along line 2-2 of FIG. 1. In FIG. 10, the plurality of element isolation grooves 18 with a predetermined width are disposed in the upper surface of the semiconductor substrate 12. As the semiconductor substrate 12, for example, a silicon substrate may be used. In the element isolation groove 18, the air gap AG is formed, and thus the element isolation groove 18 becomes the element isolation region Sb. The air gap AG is hollowed. In addition, a thin silicon oxide film may be formed on the upper surface of the silicon substrate in the air gap AG.

The element region Sa is divided into a plurality of regions by the element isolation region Sb in the horizontal direction of the drawings. On the upper surface of the semiconductor substrate 12 in the element region Sa, the gate insulating film 14 is formed, and the floating gate electrode 16a is formed on the gate insulating film 14. The gate insulating film 14, for example, is formed of a silicon oxide film. The floating gate electrode 16a, for example, is formed of a polysilicon. The floating gate electrode 16a has a triangular shape (more specifically, a substantially isosceles triangle) which protrudes upward in a cross sectional view. A first insulating film 30b, the second insulating film 32, and the third insulating film 34 are disposed on the floating gate electrode 16a. The first insulating film 30b, for example, is formed of a lanthanum aluminum silicate film (LaAlSiO).

The second insulating film 32, for example, is formed of a silicon oxide film. The third insulating film 34, for example, is formed of hafnium oxide. The first insulating film 30b is formed on the floating gate electrode 16a, and is formed such that the first insulating film 30b is slightly retreated from an end side of the floating gate electrode 16a.

An end portion 38b of the first insulating film 30b is retreated in a transverse direction to form a concave portion having a three-dimensional curvature factor. The first insulating film 30b is independently disposed on each of the floating gate electrodes 16a. The first insulating films 30b on the adjacent floating gate electrodes 16a are separated from each other, and thus are not in contact with each other.

The second insulating film 32 and the third insulating film 34 are successively disposed to lay over the plurality of floating gate electrodes 16a (over the first insulating films 30b) and the air gaps AG. On the third insulating film 34, the control gate electrode 36 is formed. The control gate electrode 36 is formed to be vertically cut in the horizontal direction of the drawing.

Furthermore, permittivities of the first insulating film 30b, the second insulating film 32, and the third insulating film 34 satisfy the following relationships.

Permittivity of the first insulating film 30b>permittivity of the second insulating film 32; and

Permittivity of the third insulating film 34>permittivity of the second insulating film 32.

According to the configuration described above, the same effects as that in the first embodiment are obtained. In addition, because of the concave portion at the end portion of the first insulating film 30b, a portion having high permittivity between the floating gates of adjacent cells is reduced, and thus, capacitance between adjacent cells decreases, and interference between adjacent cells is suppressed.

### Manufacturing Method of Second Embodiment

Next, a manufacturing method of the semiconductor memory device according to the second embodiment will be described with reference to FIGS. 10 to 13. FIGS. 10 to 13 are diagrams illustrating the manufacturing method of the NAND-type flash memory device according to the second embodiment. FIGS. 10 to 13 illustrate vertical sectional views taken along line 2-2 of FIG. 1 during different steps in the manufacturing process, and are diagrams schematically illustrating a cross sectional structure in the direction along the extending direction of the word line WL (the X direction in FIG. 1).

First, as in the first embodiment, the processes described with reference to FIGS. 3 to 5 are performed in the second embodiment. Next, to obtain the structure illustrated in FIG. 11, the element isolation insulating film 22 is embedded in the element isolation groove 18. The element isolation insulating film 22 is embedded in the element isolation groove 18, and further, is formed to be sufficiently thick in order to cover a top surface of the first insulating film 30b.

As the element isolation insulating film 22, for example, a silicon oxide film is used. The element isolation insulating film 22, for example, may be formed by forming a silicon oxide film serving as a liner film using a CVD method, then by coating the silicon oxide film with a polysilazane solution using a spin coat method, and by performing a heat treatment with respect to the silicon oxide film in a water-vapor atmosphere. The polysilazane is a polymer having a basic structure of —SiH2-NH—, and is converted into a silicon oxide film by being annealed in a water-vapor atmosphere.

Subsequently, the element isolation insulating film 22 is subjected to etching back, and is retreated such that the floating gate electrode 16a is exposed. The etching back, for example, may be performed by etching using a diluted hydrofluoric acid solution. An etching back amount of the element isolation insulating film 22 is controlled by adjusting an etching treatment time using the diluted hydrofluoric acid solution.

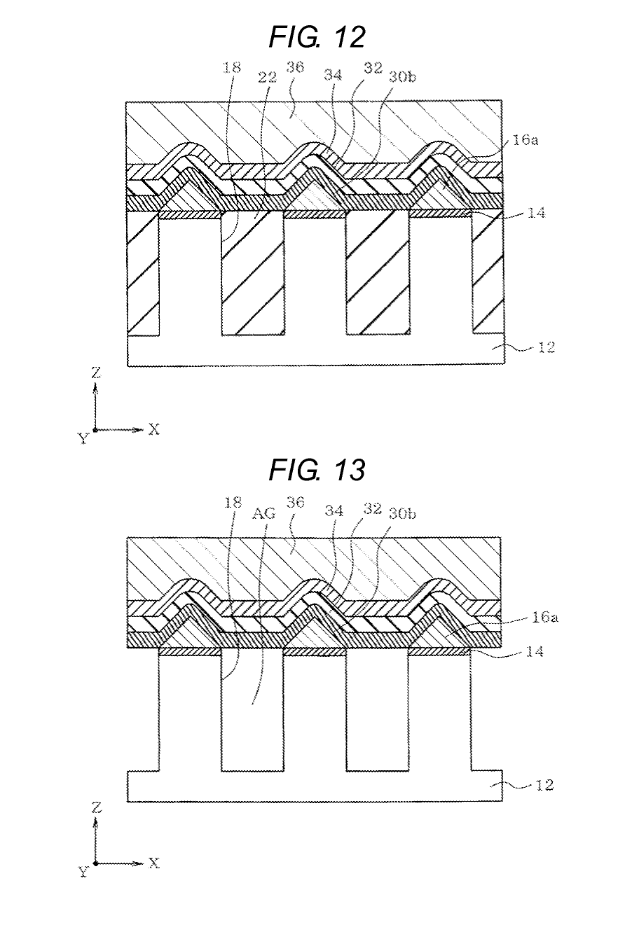

Next, to obtain the structure illustrated in FIG. 12, the first insulating film 30b is formed on the floating gate electrode 16a and the element isolation insulating film 22. As the first insulating film 30b, for example, a lanthanum aluminum silicate film (LaAlSiO) may be formed. The lanthanum aluminum silicate film, for example, may be formed by using a CVD method.

Next, the second insulating film 32, the third insulating film 34, and the control gate electrode 36 are sequentially formed in order to cover a top surface of the first insulating film 30b. As the second insulating film 32, for example, a silicon oxide film may be used. The silicon oxide film, for example, may be formed by using a CVD method. In addition, as the second insulating film 32, for example, aluminum oxide may be used instead of the silicon oxide film.

As the third insulating film 34, for example, a hafnium oxide film may be used. The hafnium oxide film, for example, may be formed by using a CVD method. In addition, as the third insulating film 34, hafnium silicate (HfSiO) in which a small amount of Si is contained in hafnium oxide may be used. In addition, a laminated structure including tantalum oxide on hafnium oxide or hafnium silicate may be used.

As the control gate electrode 36, a metallic film may be used, and for example, tungsten may be used. The tungsten, for example, may be formed by using a CVD method. In addition, as the control gate electrode 36, a conductive film may be used. For example, as the control gate electrode 36, tungsten nitride (WN) or tantalum nitride (TaN) may be used, or a laminated film thereof may be used.

Next, the floating gate electrode 16a, the first insulating film 30b, the second insulating film 32, the third insulating film 34, and the control gate electrode 36 are etched to have the shape of the word line WL illustrated in FIG. 1. The etching, for example, may be performed by using a lithography method or an RIE method. The etching is stopped at the top surface of the element isolation insulating film 22. In the region between the word lines WL, the upper surface of the element isolation insulating film 22 is exposed.

Next, to obtain the structure illustrated in FIG. 13, the element isolation insulating film 22 is removed. The element isolation insulating film 22 may be removed, for example, by using a diluted hydrofluoric acid solution. The etching using the diluted hydrofluoric acid solution is performed from the upper surface of the element isolation insulating film 22 which is exposed in the region between the word lines WL. The element isolation insulating film 22 is a coarse film, and has a high etching rate compared to other films, and thus the element isolation insulating film 22 may be selectively etched and removed. According to such a process, a region in which the element isolation insulating film 22 is disposed is hollowed, and the hollowed region becomes the air gap AG.

Furthermore, when a lanthanum content rate of the lanthanum aluminum silicate film (LaAlSiO) of the first insulating film 30b is high, an etching rate of the first insulating film 30b increases. If the etching rate is high, when a silicon oxide film is used as the element isolation insulating film 22, the element isolation insulating film 22 may not be sufficiently selectively etched and removed. In this case, as the element isolation insulating film 22, lanthanum oxide having a higher etching rate than that of the lanthanum aluminum silicate film is used, and thus the element isolation insulating film 22 may be selectively etched and removed.

Next, to obtain the structure illustrated in FIG. 10, the etching is further performed, and thus the first insulating film 30b (the lanthanum aluminum silicate film) in the air gap AG is etched. In the etching, an etching time or a concentration of an etching solution is adjusted, and as illustrated, the end portion 38b of the first insulating film 30b is retreated in the transverse direction, and thus is controlled to have a concave shape having a three-dimensional curvature factor. When the first insulating film 30b is formed of a hafnium oxide film or hafnium silicate in which a small amount of Si is contained, the etching, for example, may be performed by using sulfuric acid.

At this time, a side surface of the first insulating film 30b in the Y direction may be also etched. As necessary, it is possible to suppress the etching by performing a side surface treatment with respect to the side surface of the first insulating film 30b in the Y direction after processing the word line WL. As the side surface treatment, for example, a treatment in which a side wall is formed of a dense oxide film or a dense nitride film on a Y direction side surface of the first insulating film 30b, and a treatment in which nitride such as lanthanum aluminum silicate nitride is formed by being reacted with nitrogen immediately after processing the word line WL are able to be included. Accordingly, it is possible to increase etching resistance of the Y direction side wall of the first insulating film 30b.

After that, an interlayer insulating film, a contact, wiring, and the like are formed (not illustrated) by using a known technology, and thus the NAND-type flash memory device according to this embodiment may be formed.

### Third Embodiment

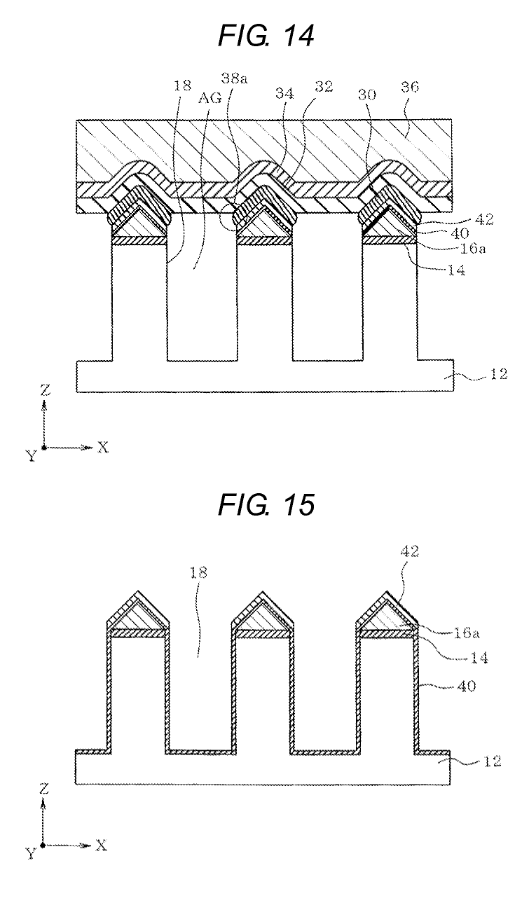

Hereinafter, a third embodiment will be described with reference to FIG. 14. FIG. 14 is a vertical sectional view illustrating a NAND-type flash memory device according to the third embodiment, and illustrates a cross section taken along line 2-2 of FIG. 1. As can be seen from FIG. 14, the difference from the first embodiment is that a fourth insulating film 40 and a second floating gate electrode 42 are formed between the floating gate electrode 16a and the first insulating film 30.

The fourth insulating film 40 and the second floating gate electrode 42 are formed on the floating gate electrode 16a along a triangular shape of the upper portion of the floating gate electrode 16a. As the fourth insulating film 40, for example, a silicon nitride film may be used. A film thickness of the silicon nitride film may be about 1 nm to 2 nm. As the second floating gate electrode 42, a metallic film (metal) may be used, and for example, ruthenium (Ru), titanium nitride (TiN), tantalum nitride (TaN), tungsten silicide (WSi), and the like are able to be used. A film thickness of the metallic film, for example, may be extremely thin, e.g., less than or equal to 1 nm. The metallic film may be in a film forming state where the metallic film is broken up to the extent that a film cannot be formed by making the film thickness thin. In this case, the metallic film may be in a state where the film is locally aggregated.

The first insulating film 30 is formed on the second floating gate electrode 42. The second insulating film 32, the third insulating film 34, and the control gate electrode 36 are disposed to cross over the first insulating film 30 and the air gaps AG. The first insulating film 30 is formed above the floating gate electrode 16a, and the end portion 38a of the first insulating film 30 is formed to slightly protrude from the side end of the floating gate electrode 16a. The width of the first insulating film 30 in the X direction is greater than the width of the floating gate electrode 16a in the X direction. The first insulating film 30 is independently disposed above each of the floating gate electrode 16a. The first insulating film 30 is separated from the first insulating films 30 on the adjacent floating gate electrodes 16a, and thus the first insulating films 30 are not in contact with each other.

The second insulating film 32 and the third insulating film 34 are successively disposed to cross over the plurality of floating gate electrodes 16a (over the first insulating film 30) and the air gap AG. The control gate electrode 36 is formed on the third insulating film 34. The control gate electrode 36 is formed to be vertically cut in the horizontal direction of the drawing.

According to the configuration described above, a charge storage effect of the second floating gate electrode 42 (metal) may be exhibited on an upper side of the floating gate electrode 16a. Here, the charge storage effect of the metal indicates that state density of a charge in the metal is high, and thus a probability of capturing an electron is high, and a height of a Fermi potential of the metal is lower than that of a floating gate electrode 16a made of polysilicon, and thus the metal easily holds the electron. Accordingly, the charge for the floating gate electrode 16a and the second floating gate electrode 42 is easily captured and held, and thus a writing speed and memory holding characteristics of the NAND-type flash memory device according to this embodiment are improved. In addition, the floating gate electrode 16a is disposed between the second floating gate electrode 42 (the metal) and the gate insulating film 14, and thus it is possible to prevent the gate insulating film 14 from being deteriorated due to diffusion of the metal in the gate insulating film 14 (a tunnel film) by direct attachment between the second floating gate electrode 42 and the gate insulating film 14. Furthermore, the height of the Fermi potential of the second floating gate electrode 42 (the metal) is low, and thus an erasing speed of the NAND-type flash memory device may be decreased. In addition, according to this embodiment, the floating gate electrode 16a (a polysilicon) exists between the gate insulating film 14 and the second floating gate electrode 42 (the metal), and thus the erasing speed may be improved.

### Manufacturing Method of Third Embodiment

Next, a manufacturing method of the semiconductor memory device according to the third embodiment will be described with reference to FIGS. 14 to 19. FIGS. 14 to 19 are diagrams illustrating the manufacturing method of the NAND-type flash memory device according to the third embodiment. FIGS. 14 to 19 illustrate vertical sectional views taken along line 2-2 of FIG. 1 during different steps in the manufacturing process, and are diagrams schematically illustrating a cross sectional structure in the direction along the extending direction of the word line WL (the X direction in FIG. 1).

First, as in the first embodiment, the processes described with reference to FIGS. 3 to 5 are performed in the third embodiment.

Next, to obtain the structure illustrated in FIG. 15, the fourth insulating film 40 is formed in the element isolation groove 18, and on the entire surface including the upper portion of the floating gate electrode 16a. As the fourth insulating film 40, for example, a silicon nitride film may be used. The silicon nitride film, for example, may be formed by using a CVD method. In addition, the silicon nitride film may be formed by nitriding a silicon upper surface (the floating gate electrode 16a, and the semiconductor substrate 12) using a thermal nitration method instead of the CVD method.

Subsequently, the second floating gate electrode 42 is formed. As the second floating gate electrode 42, a metallic (metal) film may be used, and for example, ruthenium (Ru), titanium nitride (TiN), tantalum nitride (TaN), tungsten silicide (WSi), and the like are able to be used. The metallic film, for example, may be formed by using a sputtering method or a CVD method. The metallic film may be formed under a condition producing poor coverage, and in this case, the second floating gate electrode 42 is formed only in the upper portion of the floating gate electrode 16a (a top surface portion of the fourth insulating film 40). The fourth insulating film 40 on a side surface portion of the element isolation groove 18 is exposed.

Furthermore, when the metallic film used for the second floating gate electrode 42 described above is formed, the metallic film may be stacked in the element isolation groove 18. The metallic film stacked in the element isolation groove 18 may be removed by performing a treatment using hydrochloric acid after forming the first insulating film 30 described later.

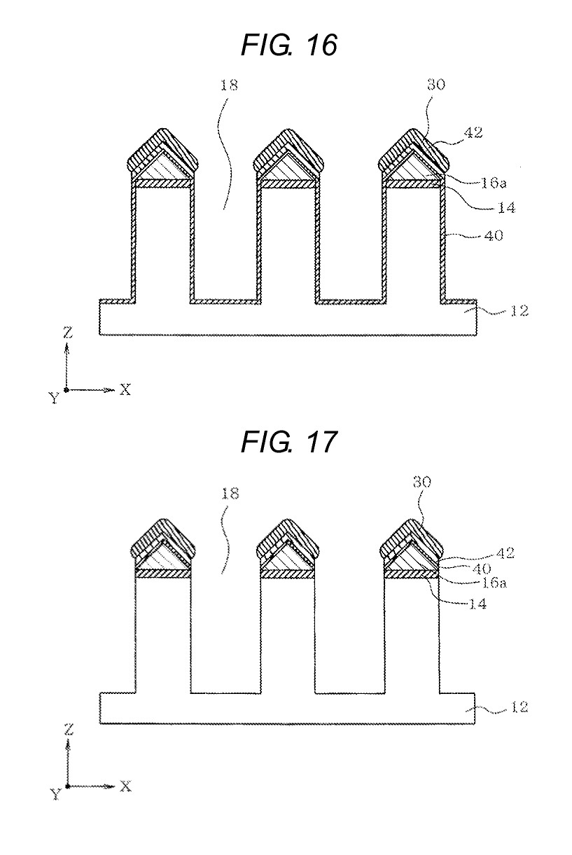

Next, to obtain the structure illustrated in FIG. 16, the first insulating film 30 is formed on the second floating gate electrode 42. As the first insulating film 30, for example, a hafnium oxide film (HfOₓ) may be formed. Here, X is an arbitrary number, and hafnium oxide may be prepared as a compound of an arbitrary composition ratio. The hafnium oxide, for example, may be formed by using a CVD method. As the first insulating film 30, hafnium silicate (HfSiO) in which a small amount of Si is contained in hafnium oxide may be used.

The first insulating film 30 may be formed by using a condition having poor coverage. The first insulating film 30 is formed under the condition producing the poor coverage, and thus the first insulating film 30 is formed to cover only the upper portion of the floating gate electrode 16a, and is not formed in the element isolation groove 18. The first insulating film 30 is formed on the top surface of the floating gate electrode 16a such that the end portion 38a slightly protrudes from an end side of the floating gate electrode 16a. The width of the first insulating film 30 in the X direction is greater than the width of the floating gate electrode 16a in the X direction.

The first insulating film 30 may be thinly formed in the element isolation groove 18 at the time of forming the first insulating film. In this case, the thin first insulating film 30 which is stacked on the upper surface in the element isolation groove 18 by a wet etching may be removed such that the first insulating film 30 on the thickly stacked floating gate electrode 16a remains. When hafnium oxide, hafnium silicate, and the like are used as the first insulating film 30, sulfuric acid may be used as a chemical solution used for the wet etching.

Next, to obtain the structure illustrated in FIG. 17, the fourth insulating film 40 of the side surface portion of the element isolation groove 18 is removed. The fourth insulating film 40, for example, may be removed by wet etching using hot phosphoric acid. Furthermore, by performing a hydrochloric acid (HCl) treatment before a hot phosphoric acid treatment, the second floating gate electrode 42 may be formed by performing a treatment of removing a metallic film which may be formed in the element isolation groove 18.

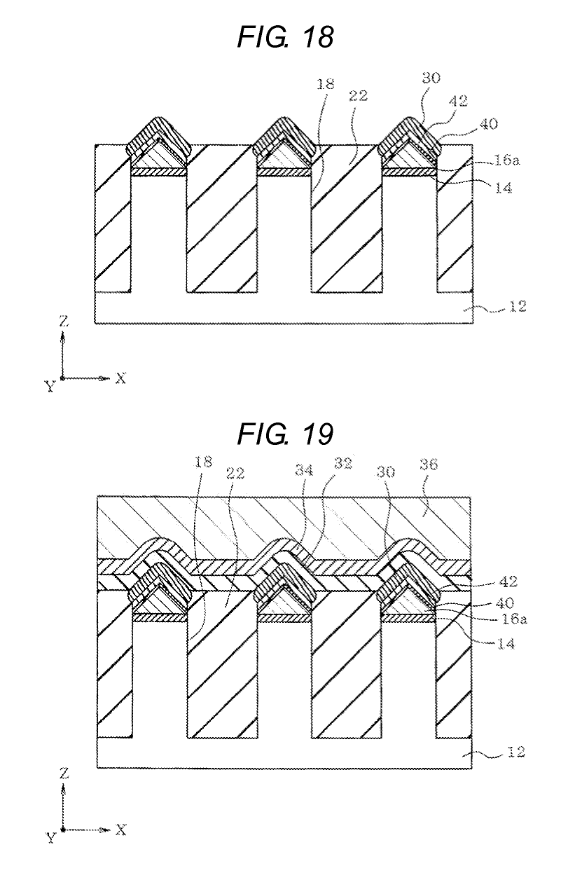

Next, to obtain the structure illustrated in FIG. 18, the element isolation insulating film 22 is embedded in the element isolation groove 18. A forming method of the element isolation insulating film 22 in this third embodiment is identical to a method performed in FIG. 7 according to the first embodiment.

Next, to obtain the structure illustrated in FIG. 19, the second insulating film 32, the third insulating film 34, and the control gate electrode 36 are sequentially formed in order to cover the top surface of the first insulating film 30 and the top surface of the element isolation insulating film 22. A forming method of the second insulating film 32, the third insulating film 34, and the control gate electrode 36 is identical in this third embodiment to a method performed in FIG. 8 according to the first embodiment. Next, the floating gate electrode 16a, the first insulating film 30, the second insulating film 32, the third insulating film 34, and the control gate electrode 36 are etched to be into the shape of the word line WL illustrated in FIG. 1. The etching, for example, may be performed by using a lithography method or an RIE method. The etching is stopped at the top surface of the element isolation insulating film 22. In a region between the word lines WL, the upper surface of the element isolation insulating film 22 is exposed.

Next, to obtain the structure illustrated in FIG. 14, the element isolation insulating film 22 is removed. The element isolation insulating film 22 may be removed, for example, by using a diluted hydrofluoric acid solution. The element isolation insulating film 22 is a coarse film, and has a high etching rate compared to other films, and thus the element isolation insulating film 22 may be selectively etched and removed. According to such a process, the region in which the element isolation insulating film 22 is disposed is hollowed, and the hollowed region becomes the air gap AG.

After that, an interlayer insulating film, a contact, wiring, and the like are formed (not illustrated) by using a known technology, and thus the NAND-type flash memory device according to this embodiment may be formed.

### Fourth Embodiment

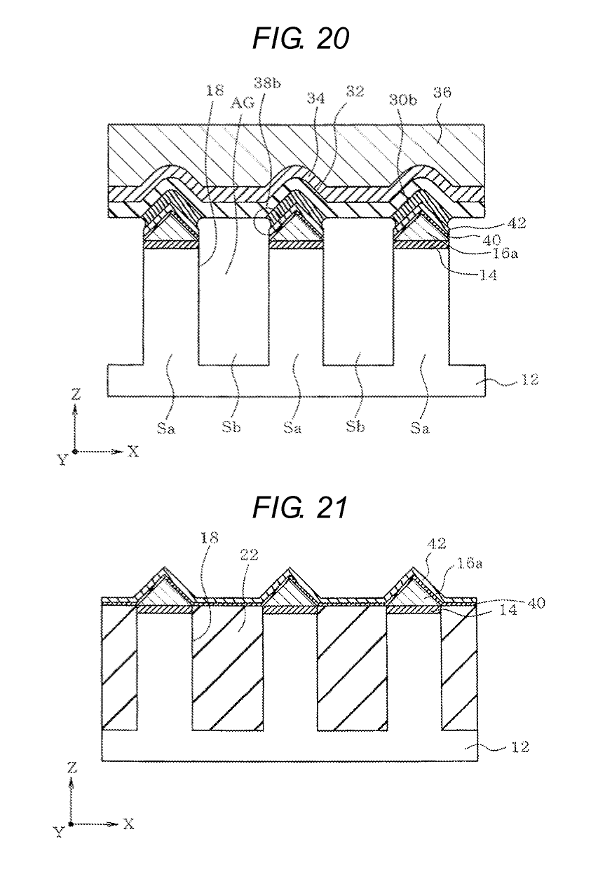

Hereinafter, a fourth embodiment will be described with reference to FIG. 20. FIG. 20 is a vertical sectional view illustrating a NAND-type flash memory device according to the fourth embodiment, and illustrates a cross section taken along line 2-2 of FIG. 1. In FIG. 20, a difference from the second embodiment is that the fourth insulating film 40 and the second floating gate electrode 42 are formed between the floating gate electrode 16a and the first insulating film 30b.

The fourth insulating film 40 and the second floating gate electrode 42 are formed on the floating gate electrode 16a along a triangular shape of the upper portion of the floating gate electrode 16a. As the fourth insulating film 40, for example, a silicon nitride film may be used. A film thickness of the silicon nitride film may be about 1 nm to 2 nm. As the second floating gate electrode 42, a metallic film (metal) may be used, and for example, ruthenium (Ru), titanium nitride (TiN), tantalum nitride (TaN), tungsten silicide (WSi), and the like are able to be used. A film thickness of the metallic film, for example, may be extremely thin, e.g., less than or equal to 1 nm. In addition, the metallic film may be in a film forming state where the metallic film is broken up to the extent that a film cannot be formed by making the film thickness thin. In this case, the metallic film may be in a state where the film is locally aggregated.

The first insulating film 30b is formed on the second floating gate electrode 42. The second insulating film 32, the third insulating film 34, and the control gate electrode 36 are disposed to cross over the first insulating film 30b and the air gaps AG. Similar to the second embodiment, the first insulating film 30b is formed above the floating gate electrode 16a, and is disposed on the floating gate electrode 16a such that the first insulating film 30b is slightly retreated from an end side of the floating gate electrode 16a. The end portion of the first insulating film 30b is retreated in the transverse direction to form a concave portion having a three-dimensional curvature factor. The first insulating film 30b is independently disposed on each of the floating gate electrodes 16a. The first insulating films 30b on the adjacent floating gate electrodes 16a are separated from each other, and thus are not in contact with each other.

According to the configuration described above, the same effects as that in the first embodiment, the second embodiment, and the third embodiment are obtained.

### Manufacturing Method of Fourth Embodiment

Next, a manufacturing method of the semiconductor memory device according to the fourth embodiment will be described with reference to FIGS. 20 to 24. FIGS. 20 to 24 are diagrams illustrating the manufacturing method of the NAND-type flash memory device according to the fourth embodiment. FIGS. 20 to 24 illustrate vertical sectional views taken along line 2-2 of FIG. 1 during different steps in the manufacturing process procedure, and are diagrams schematically illustrating a cross sectional structure in the direction along the extending direction of the word line WL (the X direction in FIG. 1).

First, as in the first embodiment, the processes described with reference to FIGS. 3 to 5 are performed in the fourth embodiment. Next, as in the second embodiment, the process described with reference to FIG. 11 is performed in the fourth embodiment.

Next, to obtain the structure illustrated in FIG. 21, the fourth insulating film 40 and the second floating gate electrode 42 are sequentially formed on the floating gate electrode 16a and the element isolation insulating film 22. As the fourth insulating film 40, for example, a silicon nitride film may be used. The silicon nitride film, for example, may be formed by using a CVD method or a thermal nitration method. When the silicon nitride film is formed by using the thermal nitration method, the silicon nitride film is formed only on the floating gate electrode 16a. As the second floating gate electrode 42, a metallic (metal) film may be used, and for example, ruthenium (Ru), titanium nitride (TiN), tantalum nitride (TaN), tungsten silicide (WSi), and the like are able to be used. The metallic film, for example, may be formed by using a sputtering method or a CVD method.

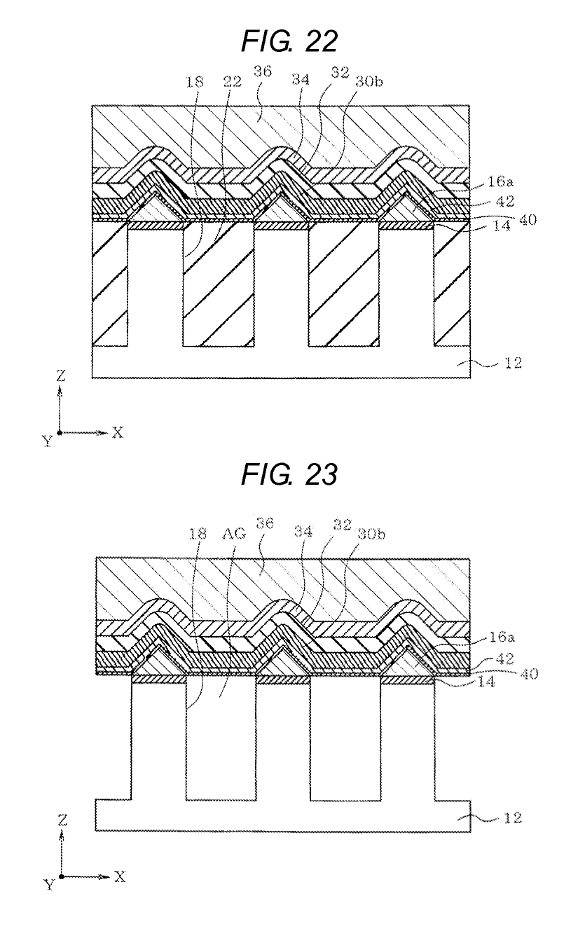

Next, to obtain the structure illustrated in FIG. 22, the first insulating film 30b is formed on the second floating gate electrode 42. As the first insulating film 30b, for example, a lanthanum aluminum silicate film (LaAlSiO) may be formed. The lanthanum aluminum silicate film, for example, may be formed by using a CVD method.

Next, the second insulating film 32, the third insulating film 34, and the control gate electrode 36 are sequentially formed in order to cover the top surface of the first insulating film 30b. As the second insulating film 32, for example, a silicon oxide film may be used. The silicon oxide film, for example, may be formed by using a CVD method. In addition, as the second insulating film 32, aluminum oxide may be used instead of the silicon oxide film. As the third insulating film 34, for example, a hafnium oxide film may be used. The hafnium oxide film, for example, may be formed by using a CVD method. In addition, as the third insulating film 34, hafnium silicate (HfSiO) in which a small amount of Si is contained in hafnium oxide may be used. In addition, a laminated structure including tantalum oxide on hafnium oxide or hafnium silicate may be used.

As the control gate electrode 36, a metallic film may be used, and for example, tungsten may be used. The tungsten, for example, may be formed by using a CVD method. In addition, as the control gate electrode 36, a conductive film may be used. For example, as the control gate electrode 36, tungsten nitride (WN) or tantalum nitride (TaN) may be used, or a laminated film thereof may be used.

Next, the floating gate electrode 16a, the first insulating film 30b, the second insulating film 32, the third insulating film 34, and the control gate electrode 36 are etched to be into the shape of the word line WL illustrated in FIG. 1. The etching, for example, may be performed by using a lithography method or an RIE method. The etching is stopped at the top surface of the element isolation insulating film 22. In the region between the word lines WL, the upper surface of the element isolation insulating film 22 is exposed.

Next, to obtain the structure illustrated in FIG. 23, the element isolation insulating film 22 is removed. The element isolation insulating film 22 may be removed, for example, by using a diluted hydrofluoric acid solution. The etching using the diluted hydrofluoric acid solution proceeds from the upper surface of the element isolation insulating film 22 which is exposed in the region between the word lines WL. The element isolation insulating film 22 is a coarse film, and has a high etching rate compared to other films, and thus the element isolation insulating film 22 may be selectively etched and removed. According to such a process, the region in which the element isolation insulating film 22 is disposed is hollowed, and the hollowed region becomes the air gap AG.

When a lanthanum content rate of the lanthanum aluminum silicate film (LaAlSiO) of the first insulating film 30b is high, the etching rate of the first insulating film 30b increases. If the etching rate is high, when a silicon oxide film is used as the element isolation insulating film 22, the element isolation insulating film 22 may not be sufficiently selectively etched and removed. In this case, as the element isolation insulating film 22, lanthanum oxide having a higher etching rate than that of the lanthanum aluminum silicate film is used, and thus the element isolation insulating film 22 may be selectively etched and removed.

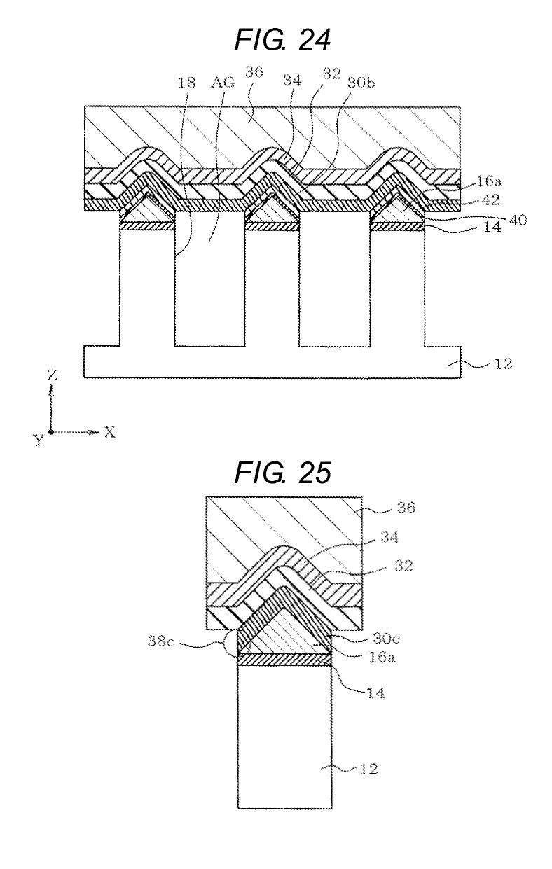

Next, to obtain the structure illustrated in FIG. 24, a portion of the fourth insulating film 40 and the second floating gate electrode 42 which is exposed in the air gap AG is etched and removed. The fourth insulating film 40, for example, may be etched by using hot phosphoric acid. The second floating gate electrode 42, for example, may be etched by using hydrochloric acid. The fourth insulating film 40 and the second floating gate electrode 42 on the floating gate electrode 16a remain. Accordingly, the first insulating film 30b is exposed in an upper portion in the air gap AG.

Next, to obtain the structure illustrated in FIG. 20, the first insulating film 30b (the lanthanum aluminum silicate film) is etched. The first insulating film 30b, for example, may be etched by using a diluted hydrofluoric acid solution. In the etching, an etching time or a concentration of an etching solution is adjusted, and as illustrated, the end portion 38b of the first insulating film 30b is retreated in the transverse direction, and thus is controlled to have a concave shape having a three-dimensional curvature factor. Furthermore, when the first insulating film 30b is formed of a hafnium oxide film or hafnium silicate in which a small amount of Si is contained, the etching, for example, may be performed by using sulfuric acid.

At this time, an end surface portion (a surface on a WL process side) of the first insulating film 30b in the Y direction may be also etched. As necessary, it is possible to suppress the etching by performing a side surface treatment with respect to an end surface of the first insulating film 30b in the Y direction immediately after the WL process. As the side surface treatment, for example, a treatment in which a side wall is formed of a dense oxide film or a dense nitride film immediately after processing the word line WL, and a treatment in which the side surface of the first insulating film 30b is formed of nitride such as lanthanum aluminum silicate nitride by adding nitrogen immediately after processing the word line WL are able to be included. Accordingly, it is possible to enhance etching resistance.

After that, an interlayer insulating film, a contact, wiring, and the like are formed (not illustrated) by using a known technology, and thus the NAND-type flash memory device according to this embodiment may be formed.

### Modification Example

FIGS. 25 to 32 are vertical sectional views respectively illustrating a modification example of each of the embodiments described above, and examples of diagrams illustrating a region R portion of FIG. 2 in an enlarged manner. FIGS. 25 to 32 are cross sectional views in a direction in which line 2-2 of FIG. 1 extends (the X direction in the drawing), and are cross sectional views in the direction in which the word line WL of FIG. 1 extends, that is, in a direction which is substantially perpendicular to the direction in which the element region Sa extends.

FIG. 25 illustrates a modification example in which the end portion of the first insulating film 30 in the first embodiment is in the shape of a perpendicular straight line. In the first embodiment, following the process of removing the element isolation insulating film 22 described in the processes of FIG. 2, the etching time or the concentration of the etching solution is adjusted, and the end portion of the first insulating film 30 is further etched, and thus it is possible to form a first insulating film 30c of which an end portion 38c is in the shape of a substantially straight line. In the modification example, the same effects as that in the first embodiment are obtained.

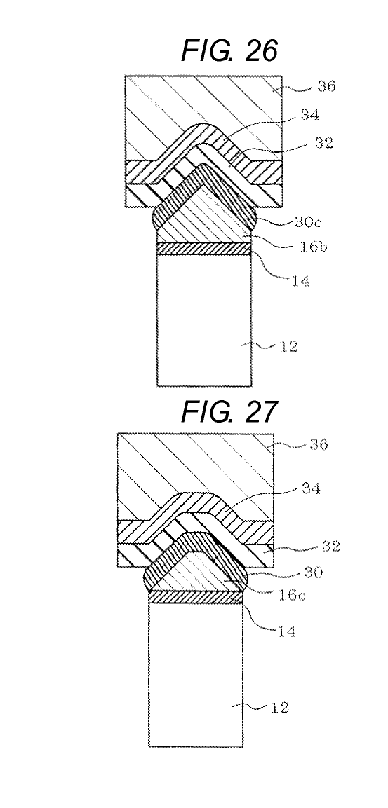

FIGS. 26 to 31 illustrate modification examples in which the floating gate electrode 16a in the first embodiment has various shapes. In the first embodiment, the condition of the slimming treatment with respect to the polysilicon film 16 which is described in the process illustrated in FIG. 5 is changed, and thus it is possible to make various shapes.

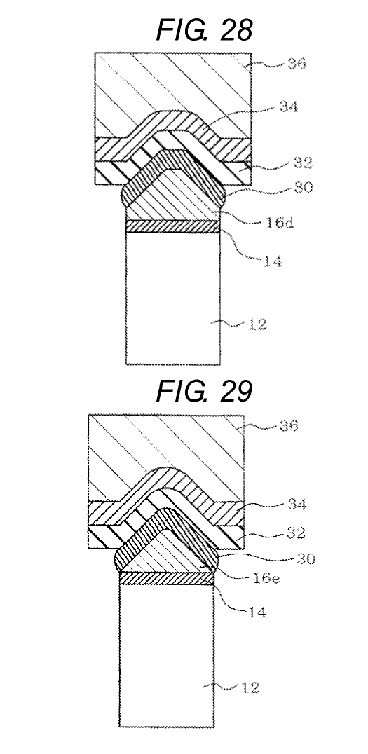

FIG. 26 illustrates a modification example in which a floating gate electrode 16b having a shape protruding upward as a whole and having a pentagonal shape with a bottom surface, side surfaces disposed substantially perpendicular to the bottom surface, and inclined surfaces connected at a vertex in a vertical section is exemplified. FIG. 27 illustrates a modification example in which a floating gate electrode 16c having a trapezoidal shape with a bottom surface, a top surface smaller than the bottom surface, and inclined surfaces connecting the top surface and the bottom surface in a vertical section is exemplified. FIG. 28 illustrates a modification example in which a floating gate electrode 16d having a hexagonal shape with a bottom surface, side surfaces disposed substantially perpendicular to the bottom surface, inclined surfaces, and a top surface smaller than the bottom surface between the inclined surfaces in a vertical section is exemplified.

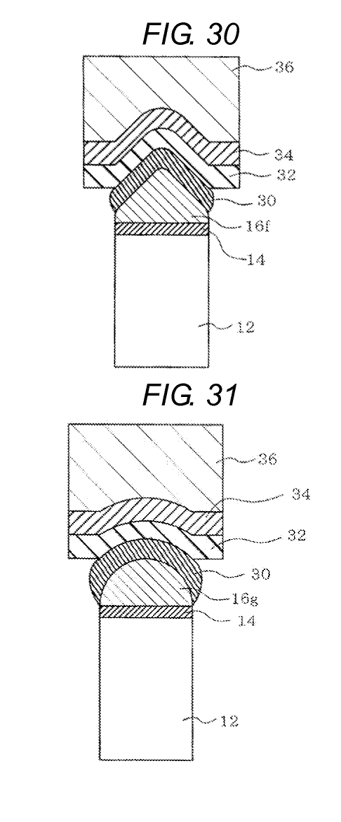

FIG. 29 illustrates a modification example in which a floating gate electrode 16e having a triangular shape protruding upward as a whole and having a round shape of which a vertex (a corner portion) is rounded to have a curvature factor in a vertical section is exemplified. FIG. 30 illustrates a modification example in which a floating gate electrode 16f having a round shape where the vertex of the floating gate electrode 16b illustrated in FIG. 26 and neighboring corners (corner portions) of the vertex are rounded to have a curvature factor in a vertical section is exemplified. FIG. 31 illustrates a modification example in which a floating gate electrode 16g having a semicircular shape protruding upward in a vertical section is exemplified. Any shape may be formed by adjusting a condition of a slimming treatment. In each of the modification examples, the same effects as that in the first embodiment are obtained. In addition, the floating gate electrodes 16e and 16f have a round shape in which the vertexes (the corner portions) of the floating gate electrodes 16e and 16f are rounded, and thus electric field concentration at the corner portion is relaxed, and leakage of a charge (an electron or a hole) due to the electric field concentration may be suppressed. Accordingly, writing and erasing characteristics and data retention characteristics of the NAND-type flash memory device according to this embodiment are improved.

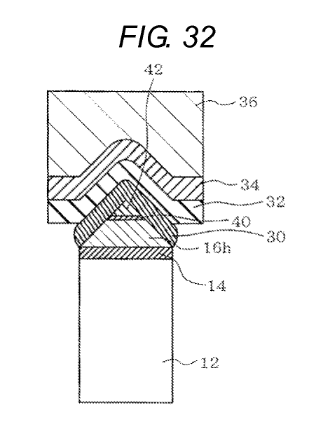

FIG. 32 illustrates a modification example in which the floating gate electrode 16a according to the first embodiment is formed as a three-layered structure of a floating gate electrode 16h, the fourth insulating film 40, and the second floating gate electrode 42 in a vertical section. Accordingly, in the modification example, the floating gate electrode 16h, the fourth insulating film 40, and the second floating gate electrode 42 have a triangular shape protruding upward as a whole. The shape may be formed by performing a slimming treatment using a condition in which a difference in etching rates of the polysilicon film 16, the fourth insulating film 40, and the second floating gate electrode 42 is small. In the modification example, the same effects as that in the third embodiment are obtained.

The modification examples are able to be applied to the first, the second, the third, and the fourth embodiments.

### Other Embodiments

In the embodiments described above, an example in which the embodiment is applied to the NAND-type flash memory device is described, and further, the embodiment may be applied to a semiconductor memory device such as a NOR-type flash memory device and an EPROM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor substrate;
first and second element regions that extend in a first direction on an upper surface of the semiconductor substrate, and are arranged in parallel along a second direction crossing the first direction;
an element isolation region that is disposed between the first element region and the second element region;
a first charge storage layer disposed above the first element region, the first charge storage layer having a first portion whose width decreases with increasing distance away from the first element region;
a second charge storage layer disposed above the second element region, the second charge storage layer having a second portion whose width decreases with increasing distance away from the second element region;
a control gate layer disposed above the first element region and the second element region;
a first insulating film disposed over of the first charge storage layer;
a second insulating film disposed over of the second charge storage layer; and
a third insulating film disposed over the first and second insulating films; and
a fourth insulating film disposed over the third insulating film.

2. The device according to claim 1,
wherein the control gate layer is disposed above the first insulating film and the second insulating film through the third insulating film and the fourth insulating film.

3. The device according to claim 1,
wherein the first insulating film and the second insulating film are not in contact with each other.

4. The device according to claim 1,
wherein the element isolation region is provided with a gap.

5. The device according to claim 1,
wherein a width of the first insulating film in the second direction is greater than a maximum width of the first charge storage layer in the second direction.

6. The device according to claim 1,
wherein each end portion of the first insulating film has a concave shape.

7. The device according to claim 1,
wherein permittivity of the first insulating film and the second insulating film are greater than permittivity of the third insulating film, and
permittivity of the fourth insulating film is greater than the permittivity of the third insulating film.

8. The device according to claim 1, further comprising:
a fifth insulating film and a first metallic film provided between the first charge storage layer and the first insulating film; and
a sixth insulating film and a second metallic film provided between the second charge storage layer and the second insulating film.

9. The device according to claim 1,
wherein the first insulating film and the second insulating film contain at least one of hafnium oxide and a lanthanum aluminum silicate film.

10. The device according to claim 8,
wherein the first metallic film and the second metallic film contain at least one of ruthenium, titanium nitride, tantalum nitride, and tungsten silicide.

11. The device according to claim 1,
wherein a cross section of the first charge storage layer has a pentagonal shape including a bottom surface, side surfaces which are substantially perpendicular to the bottom surface, and inclined surfaces.

12. The device according to claim 1,
wherein a cross section of the first charge storage layer has a trapezoidal shape including a bottom surface, a top surface which is in parallel to the bottom surface and is shorter than the bottom surface, and inclined surfaces.

13. The device according to claim 1,
wherein a cross section of the first charge storage layer has a hexagonal shape including a bottom surface, a top surface which is in parallel to the bottom surface and is shorter than the bottom surface, substantially perpendicular side surfaces, and inclined surfaces.

14. The device according to claim 1,
wherein a cross section of the first charge storage layer has triangular shape.

15. The device according to claim 14,
wherein the triangular shape has base vertices and a top vertex which is rounded.

16. The device according to claim 15,
wherein the base vertices are rounded.

17. The device according to claim 1,
wherein a cross section of the first charge storage layer has a semicircular shape.

18. The device according to claim 1,
wherein each of the first insulating films covers an entire upper surface of the first charge storage layer.

19. The device according to claim 1,
wherein the first charge storage layers has a side surface that is not covered by the first insulating film, and the second charge storage layers has a side surface that is not covered by the second insulating film.

20. A semiconductor memory device comprising:
a semiconductor substrate;
a plurality of element regions that extend in a first direction on an upper surface of the semiconductor substrate, and are arranged in parallel along a second direction crossing the first direction;
an element isolation region that is disposed between the element regions;
a charge storage layer and a control gate that are disposed in each of the element regions, each of the charge storage layers having two inclined upper surfaces with an inclination angle with respect an upper surface of the corresponding element region that is between 22.5 degrees and 67.5 degrees;
a first insulating film independently disposed over each of the charge storage layers; and
second and third insulating films disposed over each of the first insulating films.
